(19) United States
(12) Patent Application Publication
(10) Pub. No.: US 2026/0129949 A1
(43) Pub. Date: May 7, 2026

(54) Package of GaN/SiC Cascode Power Device

(71) Applicant: The Hong Kong University of Science and Technology, Hong Kong (CN)

(72) Inventors: Jing CHEN, Hong Kong (CN); Ji SHU, Hong Kong (CN)

(21) Appl. No.: 19/303,464

(22) Filed: Aug. 19, 2025

Related U.S. Application Data
(60) Provisional application No. 63/690,317, filed on Sep. 4, 2024.

(51) Int. Cl. H10D 80/20; H01L 23/373; H01L 25/07

(52) U.S. Cl. CPC H10D 80/251; H10W 40/255; H10W 90/00

(57) ABSTRACT

A GaN/SiC cascode power device is formed with first and second transistor groups. The first transistor group has one or more low-voltage normally-off GaN high-electron-mobility transistors. The second group has one or more high-voltage normally-on SiC junction-field-effect transistors. A backbone layer mechanically supports respective transistors in the two transistor groups and provides electrical connectivity among the respective transistors. The backbone layer is formed by embedding a network of conductive traces on or within an insulating rigid layer. The respective transistors are mounted on the backbone layer and electrically connected via the network of conductive traces. Advantageously, bonding wires are absent in providing intra-connection between the two transistor groups. Undesirable interconnection inductances are considerably reduced such that switching loss and switching oscillation, both overstressing the power device during a switching process, are suppressed.

### ABBREVIATIONS

Al₂O₃ alumina
AlN aluminum nitride
AMB active metal brazing
DBC direct bonding copper
DPC direct plating copper

GaN gallium nitride
HEMT high-electron-mobility transistor
HV high-voltage
JFET junction field-effect transistor
LV low-voltage
MOS metal-oxide-semiconductor
MOSFET metal-oxide-semiconductor field-effect transistor
PCB printed circuit board
Si₃N₄ silicon nitride
SiC silicon carbide

### TECHNICAL FIELD

The present disclosure generally relates to a GaN/SiC cascode power device. Particularly, the present disclosure relates to packaging the GaN/SiC cascode power device for minimizing parasitic inductances.

### BACKGROUND

The GaN/SiC cascode device uses a HV normally-on SiC JFET to block a high voltage and a LV normally-off GaN HEMT to gate current has recently been proposed and demonstrated with superior switching and static performance over SiC MOSFETs. Compared with the best commercial SiC MOSFETs, the GaN/SiC cascode device replaces the trap-rich low-mobility SiC MOS channel with a high-quality high-mobility GaN 2D electron gas channel, introducing the benefits of faster switching speed and much lower conduction loss.

To fully exploit the fast-switching potential of GaN/SiC power devices, parasitic inductances are required to be minimized to mitigate switching oscillations and to suppress switching losses. For the GaN/SiC cascode device, the parasitic interconnection inductances are the most important ones as the gate of the JFET can be overstressed by the switching oscillations induced by the parasitic interconnection inductances, thereby affecting the reliability of the cascode power device. See J. SHU, Z. ZHENG and K. J. CHEN, “Protecting SiC JFET from Gate Overstress in GaN/SiC Cascode Device without Compromising Switching Performance,” IEEE Transactions on Power Electronics, pp. 5567-5575, May 2024, doi: 10.1109/TPEL.2024.3354833, and J. Shu et al., “3D Co-packaging of GaN/SiC Cascode Device for High-Frequency Power Switching Operation,” in 2024 36th International Symposium on Power Semiconductor Devices and ICs (ISPSD), Jun. 2024, pp. 486-489. doi: 10.1109/ISPSD59661.2024.10579564, the disclosures of both of which are incorporated by reference herein.

U.S. Pat. No. 9,960,153 discloses a power device formed by connecting a JFET and a MOSFET in a cascode-coupling manner, where the JFET is formed by having two component JFETs connected in parallel. In packaging the power device, the two component JFETs and MOSFET are physically connected by bonding wires, which introduce considerable amounts of inductance.

The GaN/SiC cascode power device demonstrated much faster switching speed than all commercial power devices, requiring minimized parasitic inductances. In addition, different from the conventional vertical silicon MOSFET, the GaN HEMT is planar in nature, potentially enabling new package solutions that never exist before. Therefore, there is an urgent need in the art for a new technique of packaging a GaN/SiC cascode power device with an aim of reducing inductances.

### SUMMARY

A first aspect of the present disclosure is to provide a GaN/SiC cascode power device. The GaN/SiC cascode power device comprises a first transistor group, a second transistor group and a backbone layer. The first transistor group consists of one or more LV normally-off GaN HEMTs. The second transistor group consists of one or more HV normally-on SiC JFETs. The backbone layer is used for mechanically supporting respective transistors in the first and second transistor groups and providing electrical connection among the respective transistors. Particularly, the backbone layer is formed by forming a network of conductive traces on or within an insulating rigid layer. The respective transistors are mounted on the backbone layer and are electrically connected to the network of conductive traces.

In certain embodiments, the first transistor group is arranged face-to-face with the second transistor group such that the first and second transistor groups are located on two mutually-opposite sides of the backbone layer. The insulating rigid layer includes one or more through holes such that at least one conductive trace in the network of conductive traces runs through the one or more through holes for electrically connecting the first and second transistor groups.

In certain embodiments, the first transistor group is arranged side-by-side with the second transistor group such that the first and second transistor groups are located on a same side of the backbone layer.

In certain embodiments, the second transistor group is further limited to consist of plural HV normally-on SiC JFETs. The network of conductive traces is configured to electrically connect the plural HV normally-on SiC JFETs in parallel for boosting a current capacity handleable by the GaN/SiC cascode power device.

In certain embodiments, the first transistor group is further limited to consist of plural LV normally-off GaN HEMTs. The network of conductive traces is configured to electrically connect the plural LV normally-off GaN HEMTs in parallel for boosting a current capacity handleable by the GaN/SiC cascode power device.

In certain embodiments, the first transistor group is further limited to consist of plural LV normally-off GaN HEMTs, and the second transistor group is further limited to consist of plural HV normally-on SiC JFETs. The network of conductive traces is configured to electrically connect the plural LV normally-off GaN HEMTs in parallel and to electrically connect the plural HV normally-on SiC JFETs in parallel for boosting a current capacity handleable by the GaN/SiC cascode power device.

In certain embodiments, the first transistor group is further limited to consist of a single LV normally-off GaN HEMT, and the second transistor group is further limited to consist of a single HV normally-on SiC JFET.

In certain embodiments, the GaN/SiC cascode power device further comprises one or more peripheral blocks. Each of the one or more peripheral blocks consists of one or more electronic components electrically connected to the first transistor group via the network of conductive traces. Each of the one or more electronic components may be a gate driver, a controller, or a passive electronic component.

In certain embodiments, the one or more peripheral blocks are integrated with the first transistor group.

In certain embodiments, the backbone layer is realized as a DBC layer, an AMB layer, a DPC layer, or an interposer layer.

In certain embodiments, the insulating rigid layer is composed of AlN, Al₂O₃, Si₃N₄, or another insulating material.

A second aspect of the present disclosure is to provide a power module. The power module comprises a plurality of power devices, forming half-bridge circuits or bidirectional switches or other circuits. Each of respective power devices in the plurality of power devices is formed as any one of the embodiments of the GaN/SiC cascode power device as disclosed above. Furthermore, respective insulating rigid layers of the respective power devices are planarly joined to form a single insulating sheet.

In certain embodiments, the single insulating sheet is composed of AlN, Al₂O₃, Si₃N₄, or another insulating material.

A third aspect of the present disclosure is to provide a GaN/SiC cascode power device comprising a LV normally-off GaN HEMT and a HV normally-on SiC JFET without using a backbone layer to mount the LV normally-on GaN HEMT and HV normally-on SiC JFET. In the GaN/SiC cascode power device, a first pad pattern of the LV normally-off GaN HEMT matches a second pad pattern of the HV normally-on SiC JFET. The LV normally-off GaN HEMT is directly attached to the HV normally-on SiC JFET with the first and second pad patterns aligned to form the GaN/SiC cascode power device.

Other aspects of the present disclosure are disclosed as illustrated by the embodiments hereinafter.

### BRIEF DESCRIPTION OF THE DRAWINGS

The detailed description is set forth with reference to the accompanying drawings. The drawings are provided for purposes of illustration only and merely depict example embodiments of the present disclosure. The drawings are provided to facilitate understanding of the present disclosure and shall not be deemed to limit the breadth, scope, or applicability of the present disclosure. The drawings are not to scale unless otherwise stated. Certain parts of the drawings may be exaggerated for explanation purposes and shall not be considered limiting unless otherwise specified.

FIG. 1 shows a typical circuit model of a GaN/SiC cascode power device, which is formed with a HV SiC JFET connected in a cascode configuration with a LV GaN HEMT.

FIG. 2 shows a first GaN/SiC cascode power device packaged in accordance with one of the disclosed package solutions, where the HV SiC JFET and LV GaN HEMT are arranged in a face-to-face manner.

FIG. 3A shows a second GaN/SiC cascode power device based on a stacked GaN/SiC cascode device model as shown in the first GaN/SiC cascode power device.

FIG. 3B shows a third GaN/SiC cascode power device based on the stacked GaN/SiC cascode device model as used in the second GaN/SiC cascode power device.

FIG. 4 shows a fourth GaN/SiC cascode power device packaged in accordance with one of the disclosed package solutions, where the fourth GaN/SiC cascode power device is based on the stacked GaN/SiC cascode device model as shown in the first GaN/SiC cascode power device.

FIG. 5 shows a fifth GaN/SiC cascode power device packaged in accordance with one of the disclosed package solutions, where the fifth GaN/SiC cascode power device is based on the stacked GaN/SiC cascode device model as shown in the first GaN/SiC cascode power device.

FIG. 6 shows a sixth GaN/SiC cascode power device packaged in accordance with one of the disclosed package solutions, where the HV SiC JFET and LV GaN HEMT are arranged in a side-by-side manner.

FIG. 7 shows a seventh GaN/SiC cascode power device packaged in accordance with one of the disclosed package solutions, where the seventh GaN/SiC cascode power device is based on a planar GaN/SiC cascode device model as shown in the sixth GaN/SiC cascode power device.

FIG. 8 shows an eighth GaN/SiC cascode power device packaged in accordance with one of the disclosed package solutions, where the eighth GaN/SiC cascode power device is based on a planar GaN/SiC cascode device model as shown in the sixth GaN/SiC cascode power device.

FIG. 9 shows a ninth GaN/SiC cascode power device packaged in accordance with one of parallel package solutions as disclosed herein.

FIG. 10 shows a tenth GaN/SiC cascode power device packaged in accordance with one of the disclosed parallel package solutions.

FIG. 11 shows an eleventh GaN/SiC cascode power device packaged in accordance with one of the disclosed parallel package solutions.

FIG. 12 shows a power module realized with several GaN/SiC cascode power devices as disclosed herein.

FIG. 13 shows a twelfth GaN/SiC cascode power device packaged in accordance with one of the disclosed package solutions, where the twelfth GaN/SiC cascode power device is formed by directly joining a LV GaN HEMT and a HV SiC JFET without an adapting layer in between.

### DETAILED DESCRIPTION

The present disclosure is concerned with technical solutions of packaging a GaN/SiC cascode power device or power module. In the packaging solutions, advantageously, bonding wires are absent in providing intra-connection between a HV normally-on SiC JFET and a LV normally-off GaN HEMT. Undesirable interconnection inductances in the GaN/SiC cascode power device are considerably reduced. By reducing the interconnection inductances, switching loss and switching oscillation, both of which can overstress the power device during a switching process, are advantageously suppressed.

The packaging solutions are first described and illustrated as follows. Afterwards, embodiments of the present disclosure are developed based on the packaging solutions.

In the following description, a DBC layer is used as an example of any “backbone layer”, which provides electrical insulation and selected electrical connectivity among electronic components mounted on the aforesaid backbone layer. The backbone layer can be made based on any insulating substrate, such as AlN, Al₂O₃, Si₃N₄, epoxy, polymer, etc. In certain practical situations, the DBC layer may be substituted by an AMB layer, a DPC layer, or an interposer layer, depending on the process preferred by the application scenario. The connection between chips and the backbone layer can be soldering, sintering, or any other technologies, depending on the preference of the specific application scenario.

In the drawings, the stacked configuration as shown does not indicate the actual vertical position of each part. In other words, the plotted stacked configuration can also be flipped over when the configuration is embedded into the package's lead frame of a commercial or new package solution.

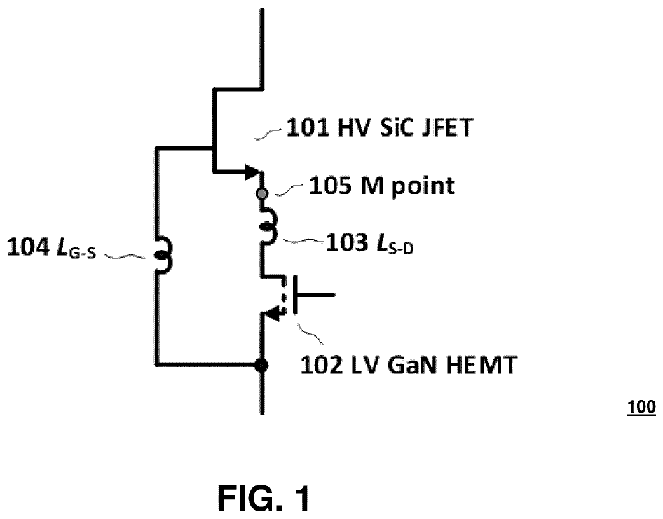

For illustration, FIG. 1 shows a typical circuit model of a GaN/SiC cascode power device 100, which is formed with a HV normally-on SiC JFET 101 connected in a cascode manner with a LV normally-off GaN HEMT 102. Regarding the cascode connection, a source of the HV normally-on SiC JFET 101 is connected to a drain of the LV normally-off GaN HEMT 102. The connection point between the source of the HV normally-on SiC JFET 101 and the drain of the LV normally-off GaN HEMT 102 is referred to as an M point 105. A gate of the HV normally-on SiC JFET 101 is connected to a source of the LV normally-off GaN HEMT 102 for biasing. Parasitic interconnection inductances, which include L_{S-D} 103 and L_{G-S} 104, are required to be minimized for achieving fast switching and suppressing switching losses of the GaN/SiC cascode power device.

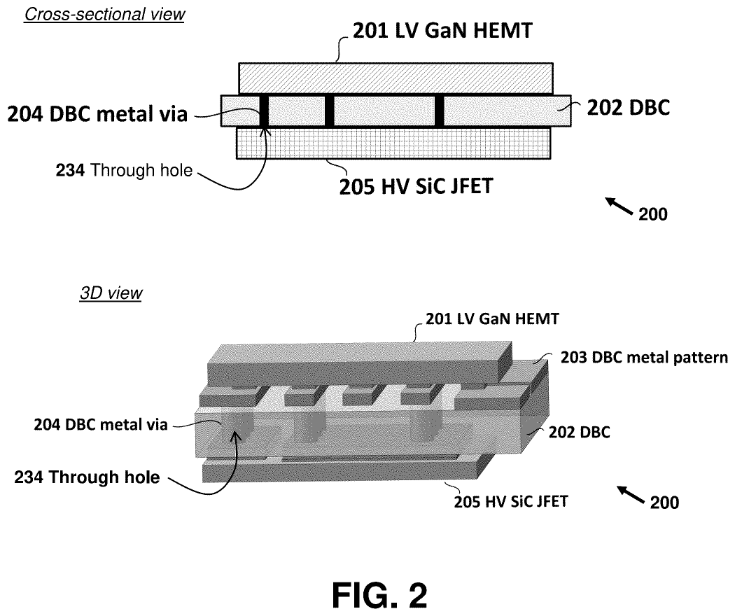

FIG. 2 shows a first GaN/SiC cascode power device 200 packaged in accordance with one of the disclosed package solutions. Cross-sectional and 3D views of the power device 200 are shown in FIG. 2. In the power device 200, LV normally-off GaN HEMT 201, DBC layer 202 and HV normally-on SiC JFET 205 are stacked. The interconnection between the LV GaN HEMT 201 and the HV SiC JFET 205 is realized with metal patterns 203 on the DBC layer 202, and with metal vias 204 within the DBC layer 202. Each of the metal vias 204 is formed by depositing metal in a through hole 234 in the substrate of the DBC layer 202. The substrate of the DBC layer 202 can be AlN, Si₃N₄, Al₂O₃, or other materials with electrical insulation capability. The metallic material of the patterns 203 and vias 204 can be any conducting metal, such as copper. The connection between chips and the backbone layer can be established by soldering, silver sintering, copper sintering, etc. Peripheral components such as gate drivers, controllers, and passive components can be monolithically integrated into the GaN HEMT 201.

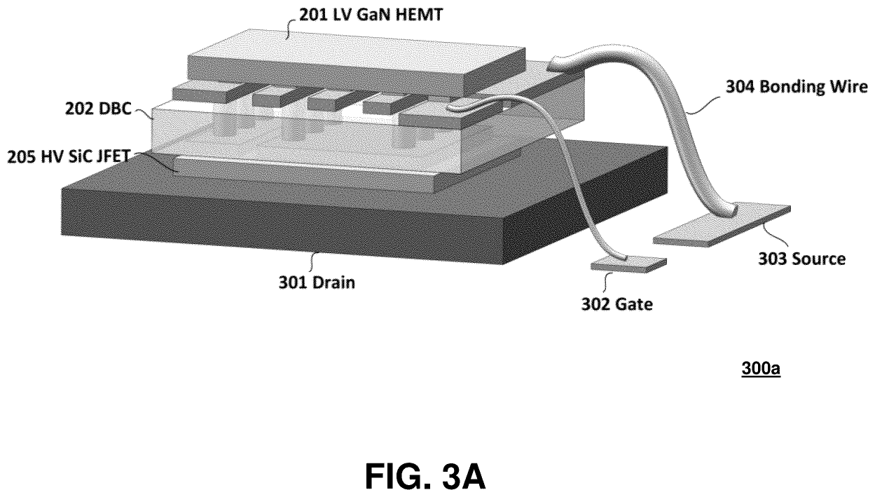

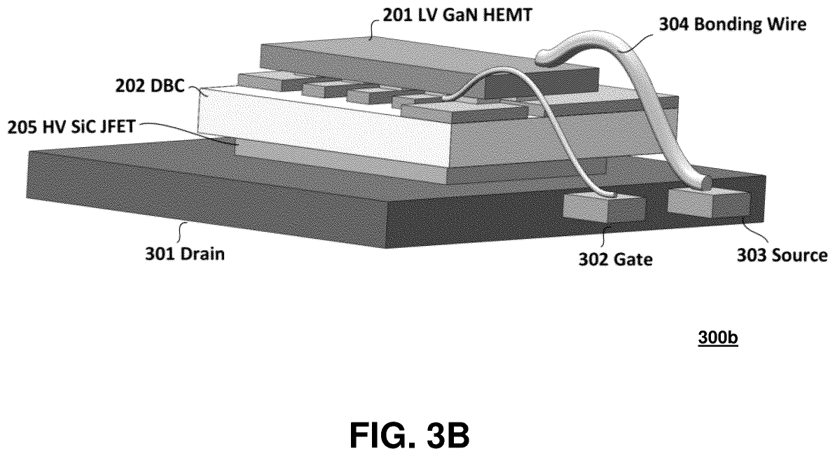

FIGS. 3A and 3B show a second GaN/SiC cascode power device 300a and a third GaN/SiC cascode power device 300b, respectively, both based on a stacked GaN/SiC cascode device model as shown in the first GaN/SiC cascode power device 200. In both power devices 300a, 300b, the stacked GaN/SiC cascode device can be embedded into a lead frame of any commercial or new package solutions, such as TO247, TO263, PCB-embedded package, etc.

In the second GaN/SiC cascode power device 300a, a drain terminal 301 of the power device 300a can be directly attached to the lead frame for the purpose of power dissipation and electrical connection. Gate terminal 302 and source terminal 303 of the power device 300a can be connected to the lead frame by one or more bonding wires (e.g., a bonding wire 304) or copper clips.

In the third GaN/SiC cascode power device 300b, the substrate of the HEMT 201 can be connected to HEMT 201's source terminal with through-GaN vias such that the HEMT 201's backside substrate can form a source terminal of the third GaN/SiC cascode device 300b. As a result, the source-terminal bonding wire 304 or copper clips of the third GaN/SiC cascode power device 300b can be connected to the HEMT 201's substrate,

The M point of each of the second and third GaN/SiC cascode power devices 300a, 300b can also be connected to an external pad of the package solution under consideration with bonding wire or copper clips.

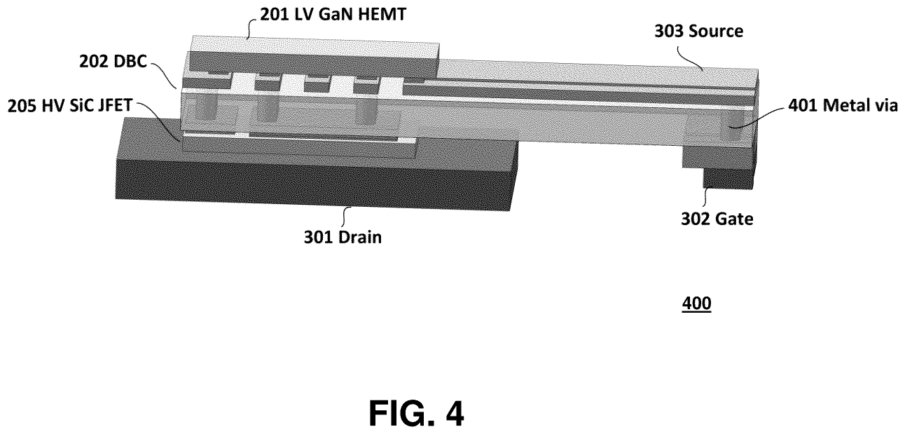

FIG. 4 shows a fourth GaN/SiC cascode power device 400 packaged in accordance with one of the disclosed package solutions. The power device 400 is based on a stacked GaN/SiC cascode device model as shown in the first GaN/SiC cascode power device 200. The drain terminal 301 of the power device 400 can be directly attached to the lead frame for the purpose of power dissipation and electrical connection. The gate terminal 302 and source terminal 303 of the power device 400 can be connected to the lead frame by metal vias 401 through the DBC layer 202. The M point 105 of the fourth GaN/SiC cascode power device 400 can also be connected to an external pad of the package solution under consideration with vias through the DBC layer 202.

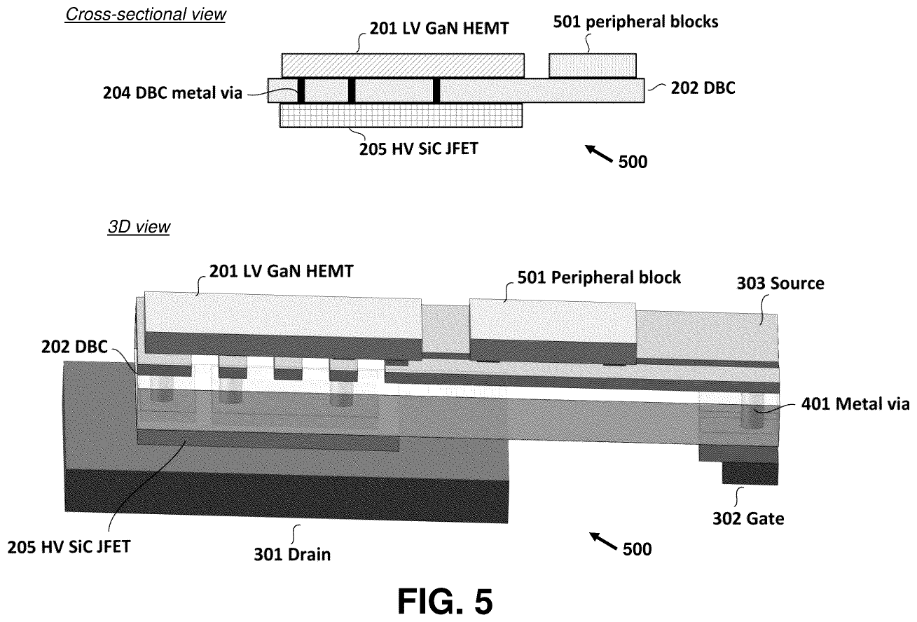

FIG. 5 shows a fifth GaN/SiC cascode power device 500 packaged in accordance with one of the disclosed package solutions. The power device 500 is based on a stacked GaN/SiC cascode device model as shown in the first GaN/SiC cascode power device 200. Cross-sectional and 3D views of the power device 500 are shown in FIG. 5. One or several peripheral blocks 501 including but not limited to gate drivers, controllers, capacitors and resistors can be connected onto the same DBC layer 202 or another DBC layer. The drain terminal 301 of the power device 500 can be directly attached to the lead frame for the purpose of power dissipation and electrical connection. The gate terminal 302, source terminal 303 and M point 105 of the fifth GaN/SiC cascode power device 500 can be connected to the lead frame by wire bonding or by metal vias through the DBC layer 202. The HEMT 201's substrate can be connected to HEMT 201's source terminal with through-GaN vias, such that the HEMT 201's backside substrate can be the source terminal of the fifth GaN/SiC cascode power device 500.

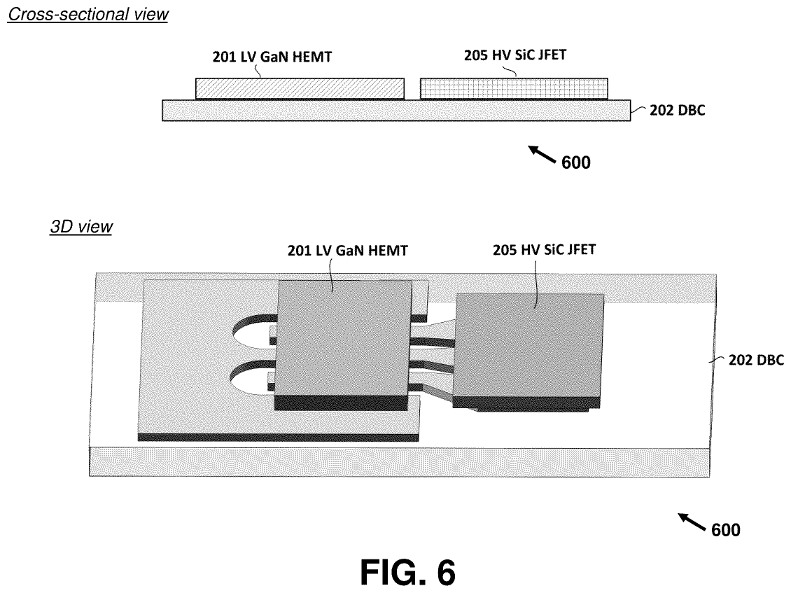

FIG. 6 shows a sixth GaN/SiC cascode power device 600 packaged in accordance with one of the disclosed package solutions. Cross-sectional and 3D views of the power device 600 are shown in FIG. 6. In the power device 600, the LV GaN HEMT 201 and HV SiC JFET 205 can be arranged in a side-by-side manner and put on the same side of the DBC layer 202. Peripheral components such as gate drivers, controller, and passive components can be monolithically integrated into the LV normally-off GaN HEMT 201.

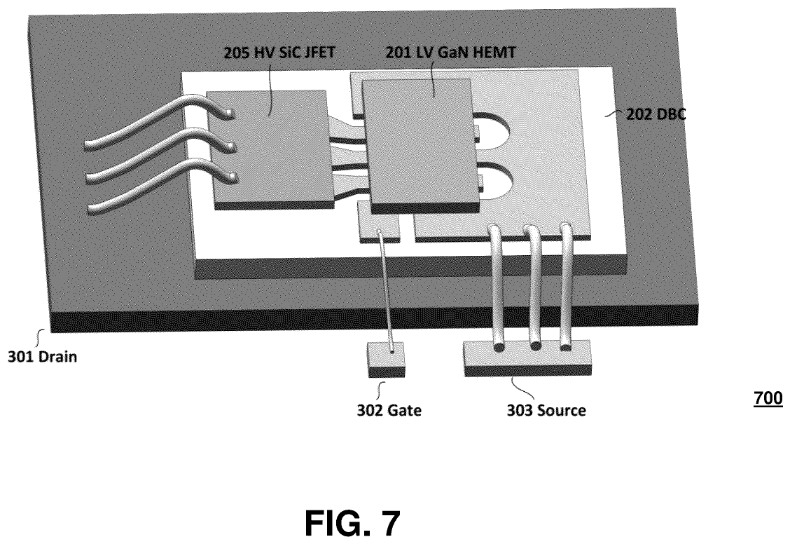

FIG. 7 shows a seventh GaN/SiC cascode power device 700 packaged in accordance with one of the disclosed package solutions. The power device 700 is based on a planar GaN/SiC cascode device model as shown in the sixth GaN/SiC cascode power device 600. The HEMT 201 and JFET 205 of the power device 700 are located on the same side of the DBC layer 202, and can be embedded into a lead frame of any commercial or new package solutions, such as TO247, TO263, PCB-embedded package, etc. The DBC layer 202 can be directly attached to the lead frame. The connection between the GaN/SiC cascode device (formed by the two transistors 201, 205) and the lead frame of the commercial package solution can be bonding wire, copper clip, or vias through the DBC layer 202. The HEMT 201's substrate can be connected to HEMT 201's source terminal with through-GaN vias, such that the HEMT 201's back-side substrate can be the source terminal of the seventh GaN/SiC cascode power device 700.

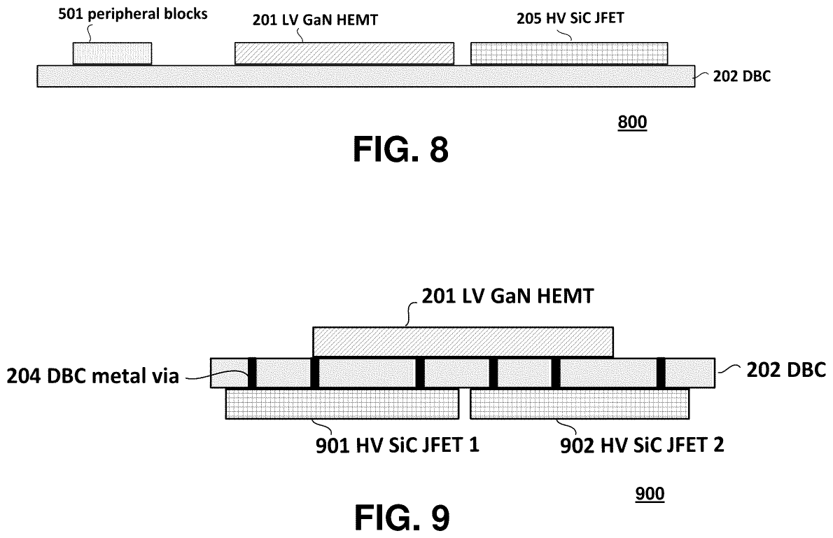

FIG. 8 shows an eighth GaN/SiC cascode power device 800 packaged in accordance with one of the disclosed package solutions. The power device 800 is based on a planar GaN/SiC cascode device model as shown in the sixth GaN/SiC cascode power device 600. The LV GaN HEMT 201 and the HV SiC JFET 205 can be arranged in a side-by-side manner and put on the same side of the DBC layer 202. One or several peripheral blocks 501 such as gate drivers, resistors, and capacitors can also be packaged onto the same DBC layer 202 or another DBC layer. The connection among different blocks and devices is realized with the metal pattern or wire bonding on the DBC layer 202.

FIG. 9 shows a ninth GaN/SiC cascode power device 900 packaged in accordance with one of parallel package solutions as disclosed herein. The power device 900 comprises a LV GaN HEMT 201 and one or several HV SiC JFETs (e.g., first HV SiC JFET 901 and/or second HV SiC JFET 902). The LV GaN HEMT 201 can be connected to the one or several SiC JFETs 901, 902 through the DBC layer 202. The LV GaN HEMT 201 and the one or several SiC JFETs 901, 902 can be arranged face-to-face through the DBC layer 202, or side-by-side on the same side of the DBC layer 202. Peripheral components such as gate drivers and passive components can be integrated into the LV GaN HEMT 201. The power device 900 can be embedded into a lead frame of any commercial or new package solutions, such as TO247, TO263, and PCB-embedded package, etc. The connection between the power device 900 and the lead frame of the commercial package solution can be bonding wires, copper clips, or vias through the DBC layer 202.

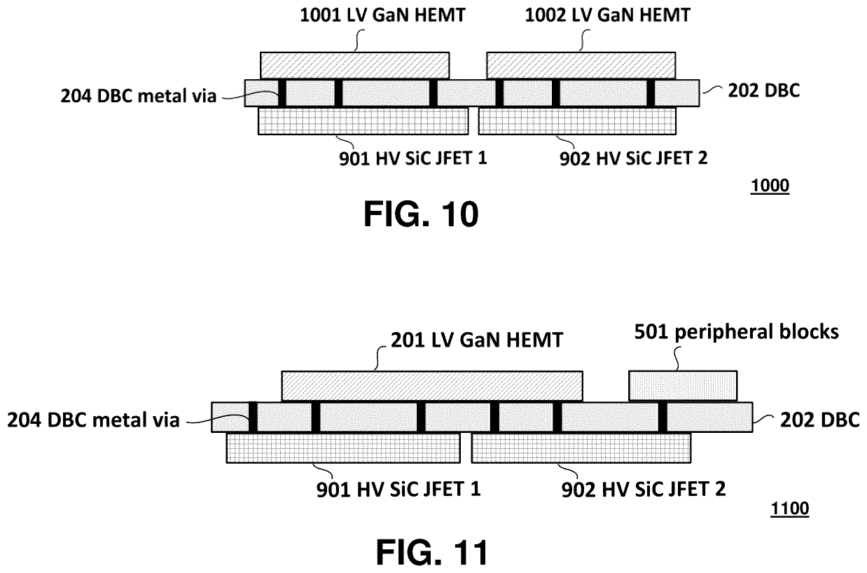

FIG. 10 shows a tenth GaN/SiC cascode power device 1000 packaged in accordance with one of the disclosed parallel package solutions. The power device 1000 comprises one or several LV GaN HEMTs (e.g., first LV GaN HEMT 1001 and/or second LV GaN HEMT 1002) and one or several HV SiC JFETs (e.g., first HV SiC JFET 901 and/or second HV SiC JFET 902). The one or several LV GaN HEMTs 1001, 1002 can be connected to the one or several SiC JFETs 901, 902 through the DBC layer 202. The one or more LV GaN HEMTs 1001, 1002 and the one or more SiC JFETs 901, 902 can be arranged face-to-face through the DBC layer 202 or side-by-side on the same side of the DBC layer 202. Peripheral components such as gate drivers and passive components can be integrated into the one or several LV GaN HEMTs 1001, 1002. The power device 1000 can be embedded into a lead frame of any commercial or new package solutions, such as TO247, TO263, PCB-embedded package, etc. The connection between the power device 1000 and the lead frame of the commercial package solution can be bonding wires, copper clips, or vias through the DBC layer 202.

FIG. 11 shows an eleventh GaN/SiC cascode power device 1100 packaged in accordance with one of the disclosed parallel package solutions. The eleventh GaN/SiC cascode power device 1100 is formed by the tenth GaN/SiC cascode power device 1000 further including one or several peripheral blocks 501 such as gate drivers or passive components (resistors and capacitors etc.). The one or several peripheral blocks 501 can be connected onto the same DBC layer 202.

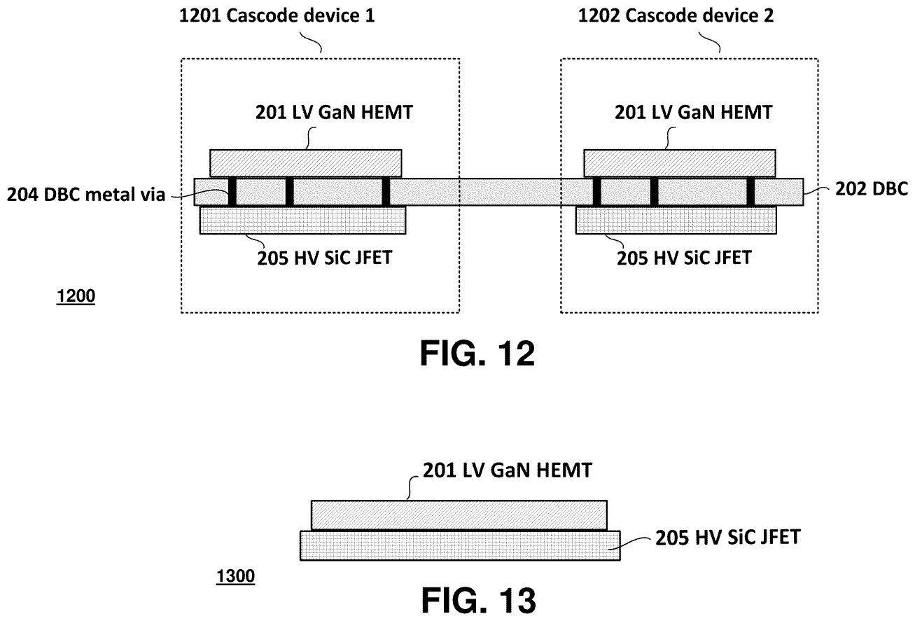

FIG. 12 shows one realization of several GaN/SiC cascode power devices (e.g. first power device 1201 and second power device 1202) in a power module 1200. The several GaN/SiC cascode power devices 1201, 1202 can be realized onto the same DBC layer 202 to form the power module 1200, such as a half-bridge and bidirectional switch. The connection between the several GaN/SiC cascode power devices 1201, 1202 can be realized by bonding wires or metal patterns on the DBC layer 202. Peripheral blocks can be integrated with the LV GaN HEMT or connected onto the DBC layer 202 as discrete components. The connection between each GaN/SiC cascode power device and the lead frame of the commercial package solution can be bonding wires, copper clips, or metal vias.

FIG. 13 shows a twelfth GaN/SiC cascode power device 1300 packaged in accordance with one of the disclosed package solutions. The power device 1300 comprises a LV GaN HEMT 210 and a HV SiC JFET 205 without an adapting DBC layer in between the HEMT 210 and the JFET 205. The pad layout of the LV GaN HEMT 210 and the HV SiC JFET 205 can be designed to match (i.e. locationally aligned with) each other such that the adapting DBC layer can be eliminated. one or more LV GaN HEMT 201 can be directly attached to one or more HV SiC JFET 205. Peripheral components such as gate drivers and passive components can be integrated into the LV GaN HEMTs. The GaN/SiC cascode device can be embedded into a lead frame of any commercial or new package solutions, such as TO247, TO263, PCB-embedded package, etc. The connection between the power device 1300 and the lead frame of the commercial package solution can be bonding wires, copper clips, or metal vias.

Embodiments of the present disclosure are developed as follows based on the details, examples, applications, etc. regarding various power devices, power modules and package solutions as disclosed above with generalization.

A first aspect of the present disclosure is to provide a thirteenth GaN/SiC cascode power device. The thirteenth GaN/SiC cascode power device generalizes various realizations of the first to eleventh GaN/SiC cascode power devices 200, 300a, 300b, 400, 500, 600, 700, 800, 900, 1000, 1100. Thus, embodiments of the thirteenth GaN/SiC cascode power device include the first to eleventh GaN/SiC cascode power devices 200, 300a, 300b, 400, 500, 600, 700, 800, 900, 1000, 1100.

Exemplarily, the thirteenth GaN/SiC cascode power device comprises a first transistor group, a second transistor group and a backbone layer. The first transistor group consists of one or more LV normally-off GaN HEMTs. The second transistor group consists of one or more HV normally-on SiC JFETs. The backbone layer is used for mechanically supporting respective transistors in the first and second transistor groups and providing electrical connectivity among the respective transistors. The backbone layer is intended to perform the same functions of the DBC layer 202 as detailed above. The backbone layer is formed by embedding a network of conductive traces on or within an insulating rigid layer. The respective transistors are mounted on the backbone layer and are electrically connected to the network of conductive traces. The network of conductive traces performs the same functions of the metal patterns 203 if the thirteenth GaN/SiC cascode power device adopts the planar GaN/SiC cascode device model, or the same functions of the metal patterns 203 plus the metal vias 204 if the thirteenth GaN/SiC cascode power device adopts the stacked GaN/SiC cascode device model.

In one approach of realizing the thirteenth GaN/SiC cascode power device, the first transistor group is arranged face-to-face with the second transistor group such that the first and second transistor groups are located on two mutually-opposite sides of the backbone layer. The insulating rigid layer includes one or more through holes such that at least one conductive trace in the network of conductive traces runs through the one or more through holes for electrically connecting the first and second transistor groups. An individual through hole in the insulating rigid layer performs the same function of the through hole 234 formed in the substrate of the DBC layer 202. Note that the individual through hole is different from each of the metal vias 204 in the DBC layer 202 in that while each of the metal vias 204 is a metallic conductor penetrating the DBC layer 202, the individual through hole is a hollow channel penetrating the insulating rigid layer and allows a conductive trace in the network of conductive traces to pass through.

In another approach of realizing the thirteenth GaN/SiC cascode power device, the first transistor group is arranged side-by-side with the second transistor group such that the first and second transistor groups are located on a same side of the backbone layer.

In one option, the second transistor group is further limited to consist of plural HV normally-on SiC JFETs. Furthermore, the network of conductive traces is configured to electrically connect the plural HV normally-on SiC JFETs in parallel for boosting a current capacity handleable by the GaN/SiC cascode power device.

In another option, the first transistor group is further limited to consist of plural LV normally-off GaN HEMTs. Furthermore, the network of conductive traces is configured to electrically connect the plural LV normally-off GaN HEMTs in parallel for boosting a current capacity handleable by the GaN/SiC cascode power device.

In yet another option, the first transistor group is further limited to consist of plural LV normally-off GaN HEMTs, as well as the second transistor group is further limited to consist of plural HV normally-on SiC JFETs. Furthermore, the network of conductive traces is configured to electrically connect the plural LV normally-off GaN HEMTs in parallel and to electrically connect the plural HV normally-on SiC JFETs in parallel for boosting a current capacity handleable by the GaN/SiC cascode power device.

In an additional option, the first transistor group is further limited to consist of a single LV normally-off GaN HEMT, as well as the second transistor group is further limited to consist of a single HV normally-on SiC JFET.

In certain embodiments, the thirteenth GaN/SiC cascode power device further comprises one or more peripheral blocks. Each of the one or more peripheral blocks consists of one or more electronic components electrically connected to the first transistor group via the network of conductive traces. Each of the one or more electronic components may be a gate driver, a controller, or a passive electronic component.

In certain embodiments, the one or more peripheral blocks are integrated with the first transistor group.

In certain embodiments, the backbone layer is realized as a DBC layer, an AMB layer, a DPC layer, or an interposer layer.

In certain embodiments, the insulating rigid layer is composed of AlN, Al₂O₃, Si₃N₄, epoxy, polymer, or another insulating material.

A second aspect of the present disclosure is to provide a first power module. The disclosed first power module generalizes the power module 1200 as disclosed above. Embodiments of the first power module include the power module 1200.

Exemplarily, the first power module comprises a plurality of power devices. In particular, each of respective power devices in the plurality of power devices is any one of the embodiments of the thirteenth GaN/SiC cascode power device disclosed above. Furthermore, respective insulating rigid layers of the respective power devices are planarly joined to form a single insulating sheet. The first power module may be manufactured by realizing the respective power devices with the single insulating sheet instead of multiple insulating rigid layers.

In certain embodiments, the single insulating sheet is composed of AlN, Al₂O₃, Si₃N₄, epoxy, polymer, or another insulating material.

A third aspect of the present disclosure is to provide a fourteenth GaN/SiC cascode power device. The fourteenth GaN/SiC cascode power device generalizes various realizations of the twelfth GaN/SiC cascode power device 1300. Embodiments of the fourteenth GaN/SiC cascode power device include the twelfth GaN/SiC cascode power device 1300.

Exemplarily, the fourteenth GaN/SiC cascode power device comprises a LV normally-off GaN HEMT and a HV normally-on SiC JFET. A first pad pattern of the LV normally-off GaN HEMT matches (i.e. locationally aligns with) a second pad pattern of the HV normally-on SiC JFET. Furthermore, the LV normally-off GaN HEMT is directly attached to the HV normally-on SiC JFET with the first and second pad patterns aligned to form the fourteenth GaN/SiC cascode power device. As a result, a backbone layer for mounting the LV normally-off GaN HEMT and HV normally-on SiC JFET is not required in the fourteenth GaN/SiC cascode power device.

The present disclosure may be embodied in other specific forms without departing from the spirit or essential characteristics thereof. The present embodiment is therefore to be considered in all respects as illustrative and not restrictive. The scope of the invention is indicated by the appended claims rather than by the foregoing description, and all changes that come within the meaning and range of equivalency of the claims are therefore intended to be embraced therein.

What is claimed is:

1. A GaN/SiC cascode power device comprising:
a first transistor group consisting of one or more low-voltage (LV) normally-off GaN high-electron-mobility transistors (HEMTs);
a second transistor group consisting of one or more high-voltage (HV) normally-on SiC junction field effect transistors (JFETs); and
a backbone layer for mechanically supporting respective transistors in the first and second transistor groups and providing electrical connectivity among the respective transistors, wherein the backbone layer is formed by embedding a network of conductive traces on or within an insulating rigid layer, the respective transistors being mounted on the backbone layer and being electrically connected to the network of conductive traces.

2. The GaN/SiC cascode power device of claim 1, wherein:
the first transistor group is arranged face-to-face with the second transistor group such that the first and second transistor groups are located on two mutually-opposite sides of the backbone layer; and
the insulating rigid layer includes one or more through holes such that at least one conductive trace in the network of conductive traces runs through the one or more through holes for electrically connecting the first and second transistor groups.

3. The GaN/SiC cascode power device of claim 1, wherein the first transistor group is arranged side-by-side with the second transistor group such that the first and second transistor groups are located on a same side of the backbone layer.

4. The GaN/SiC cascode power device of claim 1, wherein:
the second transistor group is further limited to consist of plural HV normally-on SiC JFETs; and
the network of conductive traces is configured to electrically connect the plural HV normally-on SiC JFETs in parallel for boosting a current capacity handleable by the GaN/SiC cascode power device.

5. The GaN/SiC cascode power device of claim 1, wherein:
the first transistor group is further limited to consist of plural LV normally-off GaN HEMTs; and
the network of conductive traces is configured to electrically connect the plural LV normally-off GaN HEMTs in parallel for boosting a current capacity handleable by the GaN/SiC cascode power device.

6. The GaN/SiC cascode power device of claim 1, wherein:
the first transistor group is further limited to consist of plural LV normally-off GaN HEMTs;
the second transistor group is further limited to consist of plural HV normally-on SiC JFETs; and
the network of conductive traces is configured to electrically connect the plural LV normally-off GaN HEMTs in parallel and to electrically connect the plural HV normally-on SiC JFETs in parallel for boosting a current capacity handleable by the GaN/SiC cascode power device.

7. The GaN/SiC cascode power device of claim 1, wherein:
the first transistor group is further limited to consist of a single LV normally-off GaN HEMT; and
the second transistor group is further limited to consist of a single HV normally-on SiC JFET.

8. The GaN/SiC cascode power device of claim 1 further comprising one or more peripheral blocks, wherein each of the one or more peripheral blocks consists of one or more electronic components electrically connected to the first transistor group via the network of conductive traces.

9. The GaN/SiC cascode power device of claim 8, wherein the one or more peripheral blocks are integrated with the first transistor group.

10. The GaN/SiC cascode power device of claim 8, wherein each of the one or more electronic components is a gate driver, a controller, or a passive electronic component.

11. The GaN/SiC cascode power device of claim 1, wherein the backbone layer is realized as a direct bonding copper (DBC) layer, an active metal brazing (AMB) layer, a direct plating copper (DPC) layer, or an interposer layer.

12. The GaN/SiC cascode power device of claim 1, wherein the insulating rigid layer is composed of AlN, Al₂O₃, Si₃N₄, epoxy, polymer, or another insulating material.

13. A power module comprising a plurality of power devices, wherein:
each of respective power devices in the plurality of power devices is formed as the GaN/SiC cascode power device of claim 1; and
respective insulating rigid layers of the respective power devices are planarly joined to form a single insulating sheet.

14. The power module of claim 13, wherein the single insulating sheet is composed of AlN, Al₂O₃, Si₃N₄, epoxy, polymer, or another insulating material.

15. A GaN/SiC cascode power device comprising:
a low-voltage (LV) normally-off GaN high-electron-mobility transistor (HEMT); and
a high-voltage (HV) normally-on SiC junction field effect transistor (JFET);
wherein a first pad pattern of the LV normally-off GaN HEMT matches a second pad pattern of the HV normally-on SiC JFET, and wherein the LV normally-off GaN HEMT is directly attached to the HV normally-on SiC JFET with the first and second pad patterns aligned to form the GaN/SiC cascode power device.
